(19) United States
(12) Patent Application Publication
(10) Pub. No.: US 2014/0140031 A1
(43) Pub. Date: May 22, 2014

(54) WIRELESS MODULE

(71) Applicant: Panasonic Corporation, Osaka (JP)

(72) Inventors: Suguru Fujita, Tokyo (JP); Ryosuke Shiozaki, Kanagawa (JP); Toshiaki Nakamura, Nara (JP); Jun'ichi Kimura, Osaka (JP)

(73) Assignee: Panasonic Corporation, Osaka (JP)

(21) Appl. No.: 14/131,847

(22) PCT Filed: Dec. 6, 2012
(86) PCT No.: PCT/JP2012/007826

§ 371 Date: Jan. 9, 2014

(30) Foreign Application Priority Data
Feb. 15, 2012 (JP) 2012-030897
Dec. 7, 2012 (JP) 2011-268042

(51) Int. Cl. H05K 1/18

(52) U.S. Cl. CPC H05K 1/18
USPC 361/803

(57) ABSTRACT

A wireless module, in which a first board (11) and a second board (12) are laminated, includes connecting members (18) which are connected to at least one of the first board (11) and the second board (12), and form a gap allowing mounting of mounting components including a semiconductor device (14) between the first board (11) and the second board (12). The connecting members (18) are arranged such that a plurality of connecting members (18A, 18B) are arranged uniformly in a planar direction of the boards of the wireless module.

### TECHNICAL FIELD

The present disclosure relates to a wireless module which is used for wireless communication and has an electronic component mounted on a board.

### BACKGROUND ART

As a circuit module for wireless communication having an electronic circuit mounted on a board, a circuit module is known, in which a board having an active device (for example, an integrated circuit (IC)) mounted thereon and a board having a passive device (for example, a resistor, an inductor, or a conductor) mounted thereon are arranged to face each other and electrically connected together, and the space between the boards is sealed with resin.

For example, Patent Literature 1 discloses a semiconductor apparatus as a wireless module which uses a board having an antenna as a passive device mounted thereon and a board having a semiconductor device as an active device.

In the semiconductor apparatus of Patent Literature 1, an antenna is mounted on one surface of a silicon board, a semiconductor device as an active device is mounted on the other surface of the silicon board, the antenna and the semiconductor device are electrically connected together through a through-via passing through the silicon board. A wiring board formed separately from the silicon board has a passive device mounted on one surface thereof, and the wiring board and the silicon board are electrically connected together through a connecting member provided between one surface of the wiring board and the other surface of the silicon board.

As a wireless module of a related art, a wireless module is known, in which a first board having an active device and a passive device mounted thereon and a second board having an antenna mounted thereon are arranged to face each other and electrically connected together by a connecting member. In this wireless module, a semiconductor device (for example, an IC) as an active device and a chip capacitor or a chip resistor as a passive device are mounted on the first board, and a connecting member by, for example, a solder-plated Cu (copper) core ball is mounted on the second board. The mounting surfaces of the first board and the second board are arranged to face each other, the solder of the connecting member is molten and electrically connected to the first board, and mold resin as a seal material is filled in a buried layer having a component between the boards to seal the space between the boards with a seal. Accordingly, a wireless module in which a plurality of boards are laminated is completed.

### CITATION LIST

### Patent Literature

Patent Literature 1: JP-A-2009-266979

### SUMMARY OF INVENTION

### Technical Problem

In the technique of Patent Literature 1, it is difficult to uniformly adjust the thickness of the module in the wireless module after assembling.

The present disclosure has been accomplished in consideration of the above-described situation, and an object of the present disclosure is to uniformly adjust the thickness of the module in the wireless module after assembling.

### Solution to Problem

The present disclosure provides a wireless module including: a first board on which a mounting component of a wireless circuit is mounted; a second board which is laminated on the first board; and a connecting member which is connected to at least one of the first board and the second board, and forms a gap allowing mounting of the mounting component between the first board and the second board, wherein the connecting member has a plurality of connecting members arranged uniformly between the first board and the second board.

### Advantageous Effects of Invention

According to the present disclosure, it is possible to uniformly adjust the thickness of the module in the wireless module after assembling.

### BRIEF DESCRIPTION OF DRAWINGS

FIG. 1 shows an example of the configuration of a wireless module of a related art, in which (A) is a cross-sectional view, (B) is a plan view when viewed from the top in a state where a second board is removed, and (C) is a plan view when viewed from the top of the second board.

FIG. 2 is a cross-sectional view showing the configuration of a wireless module according to a first embodiment of the present disclosure.

FIG. 3 is a plan view showing the arrangement configuration of a connecting member in the wireless module of the first embodiment.

FIG. 4 is a cross-sectional view showing the configuration of a wireless module according to a modification of the first embodiment, in which (A) shows a first modification, and (B) shows a second modification.

FIG. 5 is a plan view showing the arrangement configuration of a connecting member in a wireless module of a second embodiment.

FIG. 6 is a plan view showing the arrangement configuration of a connecting member in a wireless module of a third embodiment.

FIG. 7 is a cross-sectional view of the wireless module shown in FIG. 3 taken along the line A-A.

FIG. 8 is a plan view showing a configuration example of the periphery of a through-via connected to a ground pattern in the first to third embodiments.

FIG. 9 is a cross-sectional side view showing a configuration example of a wireless module according to a fourth embodiment of the invention.

FIG. 10 is a cross-sectional side view showing a configuration example of a wireless module according to a fifth embodiment of the invention.

FIG. 11 is a top view showing a first example of the positional relationship between an antenna unit and a waveguide unit of the wireless module according to the fifth embodiment of the invention.

FIG. 12 is a top view showing a second example of the positional relationship between an antenna unit and a waveguide unit of the wireless module according to the fifth embodiment of the invention.

FIG. 13 is a top view showing a third example of the positional relationship between an antenna unit and a waveguide unit of the wireless module according to the fifth embodiment of the invention.

### DESCRIPTION OF EMBODIMENTS

### Background to an Aspect of the Present Disclosure

In the wireless module of the related art, the connecting member connecting a plurality of boards together is electrically connected to the wiring pads provided on the boards. The connecting member and the wiring pads are arranged according to the layout of the devices mounted on the boards and the wiring patterns of the boards. For example, during manufacturing, deflection of the boards and deviation of the amount of a seal material filled between the boards may occur depending on the arrangement of the connecting member and the thickness of the module may not be uniform. If the thickness of the module is not uniform, for example, torsional stress may be applied to the boards, and the connection of contacts of the devices is incomplete, causing defective mounting. The directional characteristics of the antenna may change depending on the slope of the antenna surface of the wireless module.

This problem will be described in detail.

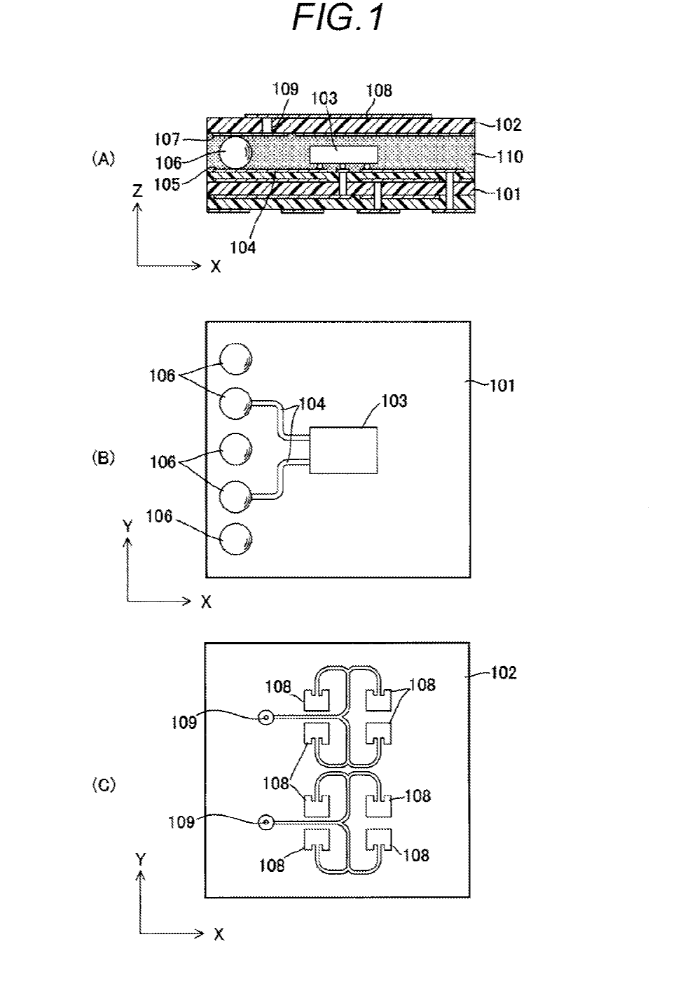

FIG. 1 shows an example of the configuration of a wireless module of the related art, in which (A) is a cross-sectional view, (B) is a plan view when viewed from the top in a state where a second board is removed, and (C) is a plan view when viewed from the top of the second board.

The wireless module has a first board 101 as a main board and a second board 102 as a sub-board. On one surface of the first board 101, a wiring pattern 104 is provided, and a mounting component of a wireless circuit, for example, a semiconductor device 103 as an active device is mounted.

A wiring pad 107 is formed on one surface of the second board 102, and a connecting member 106 is mounted on the wiring pad 107. Here, a case where a Cu core ball is used as the connecting member 106 will be described. A pad-like antenna 108 is formed on the other surface of the second board 102 and electrically connected to the wiring pad 107 on one surface of the second board 102 by a through-via 109. In the example shown in the figure, the connecting members 106 of the Cu core ball are arranged in a row near one side of the second board 102.

One surface of the first board 101 and one surface of the second board 102 are arranged to face each other, and the connecting member 106 is connected to the wiring pad 105 of the first board 101, whereby the second board 102 is electrically connected to the first board 101 by the connecting member 106. Seal resin 110 is filled in a buried layer having the semiconductor device 103 between the first board 101 and the second board 102 to seal the space between the boards.

In the structure of FIG. 1, since the connecting member 106 is arranged in an offset manner, in manufacturing the wireless module, for example, deflection of the second board 102 and deviation of the amount of seal resin 110 filled between the boards may occur, and the thickness of the module may not be uniform. In particular, in manufacturing a small wireless module for a high-frequency band, since a step of forming a plurality of modules in parallel on a single large board and dividing the board into a plurality of modules is adopted, if there is deviation of the connecting member in the module, deviation of the thickness may occur between the modules after dividing.

If the thickness of the module is not uniform, for example, torsional stress may be applied to the first board 101 and the second board 102, and defective mounting of the semiconductor device 103 may occur. A slope on the outer surface (the other surface) of the second board 102 may cause change in the directional characteristics of the antenna 108 of the wireless module.

In the following embodiments, in regard to the above-described problem, a configuration example of a wireless module capable of uniformly adjusting the thickness of the module after assembling will be described.

In the following embodiments, as an example of a wireless module according to the present disclosure, for example, several configuration examples of a wireless module used for a high-frequency band of a millimeter-wave band of 60 GHz and an antenna and a semiconductor device mounted thereon will be described.

### First Embodiment

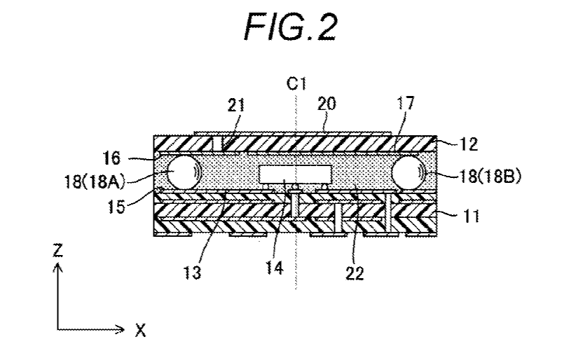

FIG. 2 is a cross-sectional view showing the configuration of a wireless module according to a first embodiment of the present disclosure.

The wireless module of this embodiment has a first board 11 as a main board and a second board 12 as a sub-board. The first board 11 and the second board 12 are formed using, for example, an insulating material of a dielectric having a dielectric constant of about 3 to 4. On one surface of the first board 11, a wiring pattern 13 by, for example, a copper foil is provided, a mounting component of a wireless circuit, for example, a semiconductor device (for example, an IC) 14 as an active device is mounted, whereby a wireless circuit is formed. The first board 11 is provided with a wiring pad 15 for electrically connecting a connecting member 18.

On one surface of the second board 12, for example, a sheet-like ground pattern 17 by a copper foil and a circular wiring pad 16 are formed, and a connecting member 18 by a Cu core ball solder-plated to the wiring pad 16 is mounted. On the other surface of the second board 12, for example, a pad-like antenna 20 by a copper foil is formed and is electrically connected to the wiring pad 16 on one surface of the second board 12 by a through-via 21. The antenna 20 is formed by one or more antenna devices. The wiring pad 16 may include a wiring pattern.

In this embodiment, the connecting member 18 is arranged uniformly in the planar direction (XY plane) of the first board 11 and the second board 12. In the example of FIG. 2, in the left-right direction (X direction) of the figure, two connecting members 18A, 18B are arranged symmetrically with respect to a center portion (board center line C1) of the boards.

One surface of the first board 11 and one surface of the second board 12 are arranged to face each other, and the solder of the connecting member 18 is molten and connected to the wiring pad 15 of the first board 11, whereby the second board 12 is electrically connected to the first board 11 by the connecting member 18. The connecting member 18 becomes a signal transmission path (signal line path) between the wireless circuit of the first board 11 and the antenna 20 of the second board 12. In the example of the figure, both connecting members 18A, 18B are connected to the first board 11 and the second board 12.

The connecting member 18 is provided so as to form a gap allowing mounting of mounting components including a semiconductor device 14 between the first board 11 and the second board 12. For example, seal resin 22 of mold resin is filled in a buried layer having the semiconductor device 14 between the first board 11 and the second board 12 to seal the space between the boards.

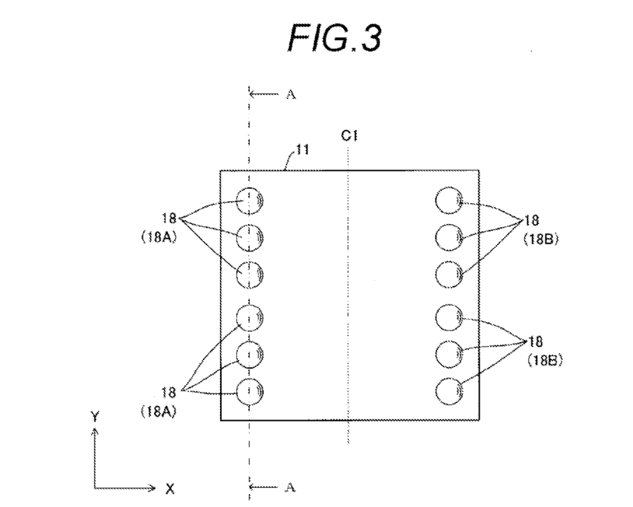

FIG. 3 is a plan view showing the arrangement configuration of a connecting member in the wireless module of the first embodiment. FIG. 3 is a plan view when viewed from the top in a state where the second board of the wireless module is removed, that is, a diagram illustrating the arrangement state of the connecting member 18 by a Cu core ball in the wireless module.

In the first embodiment, the connecting members 18 (18A, 18B) by a Cu core ball are arranged in rows six by six near two sides facing each other symmetrically with respect to the center portion in the planar direction of the boards on the first board 11 and the second board 12, that is, the board center line C1 of the external shape in the left-right, direction (X direction). That is, the connecting members 18A on the left side of the figure and the connecting members 18B on the right side of the figure are located symmetrically on the boards. Accordingly, the arrangement of the connecting member 18 is balanced uniformly on the first board 11 and the second board 12.

As described above, the connecting members 18 are arranged symmetrically on the boards, whereby it is possible to suppress torsional stress applied to the boards and to suppress deflection of the boards of the wireless module and deviation of the amount of seal resin 22 filled between the boards. The connecting members 18 function as a member which regulates the gap between the boards. For this reason, it is possible to uniformly adjust the thickness of the module and to reduce warping of the wireless module, deflection, and defective mounting due to unevenness. It is also possible to reduce the slope of the antenna surface of the wireless module and to suppress change in the antenna characteristic before and after assembling.

### Modifications

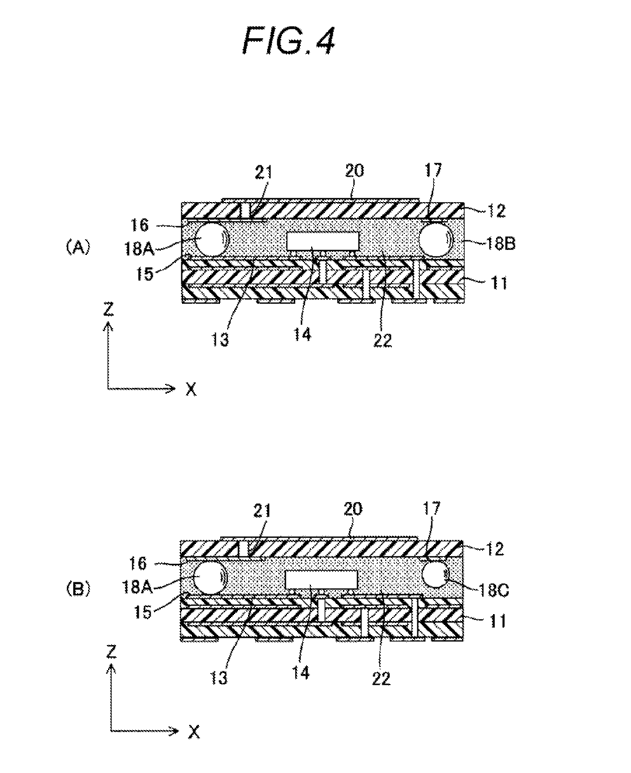

Modifications of the first embodiment will be described. FIG. 4 is a cross-sectional view showing the configuration of a wireless module according to a modification of the first embodiment, in which (A) shows a first modification, and (B) shows a second modification. In the first embodiment shown in FIG. 2, the connecting member 18A on the left side of the figure and the connecting member 18B on the right side of the figure are connected to both the first board 11 and the second board 12.

In the first modification shown in FIG. 4(A), the first connecting member 18A on the left side of the figure is connected to both the first board 11 and the second board 12, but the other second connecting member 18B on the right side of the figure is connected to the second board 12 on the upper side of the figure and is not connected to the first board 11 on the lower side of the figure. The connecting member 18B may be connected to the first board 11. That is, the second connecting member 18B is provided as a dummy Cu core ball so as to adjust the distance between the boards for board deflection prevention.

Although it is desirable that the connecting member 18 is connected to both boards, even if the connecting member 18 is connected to one board, as in the first embodiment, the effect of uniformly adjusting the thickness of the module is obtained.

In the second modification shown in FIG. 4(B), as in the first modification, a third connecting member 18C on the right side of the figure is connected to the second board 12 on the upper side of the figure and is not connected to the first board 11 on the lower side of the figure. The third connecting member 18C is different in external dimension from the first connecting member 18A on the left side of the figure, and is smaller than the connecting member 18A. The third connecting member 18C may be connected to the first board 11.

A connecting member provided as a dummy Cu core ball is different in external dimension (dimension in the module thickness direction (Z direction)) but is provided uniformly on the boards to have a function of adjusting the distance between the boards for board deflection prevention. For this reason, as in the first embodiment, the effect of uniformly adjusting the thickness of the module is obtained.

### Second Embodiment

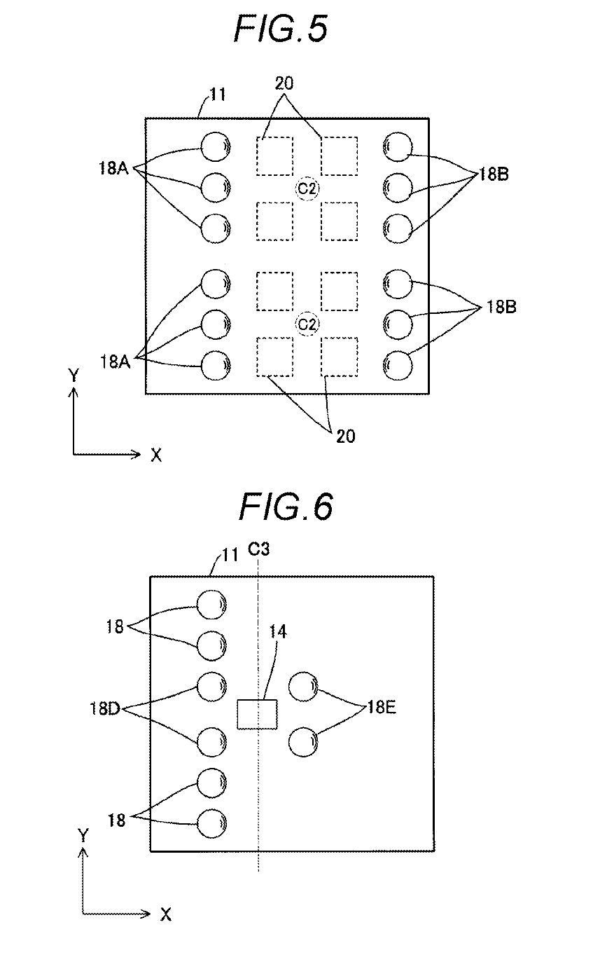

FIG. 5 is a plan view showing the arrangement configuration of a connecting member in a wireless module of a second embodiment. FIG. 5 is a plan view when viewed from the top in a state where a second board of a wireless module is removed, that is, a diagram illustrating the arrangement state of connecting members 18A, 18B by a Cu core ball in a wireless module. An antenna 20 provided on the other surface of a second board 12 is indicated by a broken line.

In the second embodiment, connecting members 18A, 18B by a Cu core ball are arranged in two rows symmetrically with respect to the planar direction (XY plane) of the antenna 20 of the second board 12. That is, the connecting members 18A on the left side of the figure and the connecting members 18B on the right side of the figure are located in two rows three by three symmetrically with respect to a center portion C2 (the center of four antennas 20) of an array of the antennas 20 by a plurality of (in the example of the figure, 2×2=4) antenna devices. In the example of the figure, two sets of 2×2 antenna arrays in total for transmission and reception are arranged.

Accordingly, the arrangement of the connecting members 18A, 18B is balanced uniformly centering on the antenna in the planar direction of the boards of the wireless module. The antenna 20 may have a single antenna device.

As described above, the connecting members 18A, 18B are arranged symmetrically with respect to the antenna 20 on the board, whereby, as in the first embodiment, it is possible to uniformly adjust the thickness of the module. In particular, since it is possible to uniformly adjust the thickness of the module centering on the antenna portion, it is possible to suppress the slope of the antenna surface of the wireless module and to reduce unintended change in antenna characteristic.

### Third Embodiment

FIG. 6 is a plan view showing the arrangement configuration of connecting members in a wireless module of a third embodiment. FIG. 6 is a plan view when viewed from the top in a state where a second board of a wireless module is removed, that is, is a diagram illustrating the arrangement state of connecting members 18A, 18B by a Cu core ball in a wireless module.

In the third embodiment, four connecting members 18D, 18E by a Cu core ball are arranged symmetrically with respect to a semiconductor device 14 as a mounting component mounted on a second board 12. That is, the connecting members 18D on the left side of the figure and the connecting members 18E on the right side of the figure are located symmetrically with respect to a center portion (a center line C3 in the left-right direction (X direction) of the figure) of the semiconductor device 14 corresponding to four corners or two opposing sides of the semiconductor device 14.

Accordingly, the arrangement of the connecting members 18D, 18E is balanced uniformly centering on the semiconductor device in the module in the planar direction of the boards of the wireless module. Other connecting members 18 are arranged in rows on an extension connecting the two connecting members 18D (in FIG. 6, a vertical direction (Y direction)).

As described above, the connecting members 18D, 18E are arranged symmetrically with respect to the semiconductor device 14 on the board, whereby, as in the first embodiment, it is possible to uniformly adjust the thickness of the module. In particular, the periphery of the semiconductor device as a mounting component is surrounded symmetrically by the connecting members, whereby it is possible to uniformly adjust the thickness of the module in a portion centering on the semiconductor device. For this reason, it is possible to further reduce warping in a portion centering on the semiconductor device.

From the above, it is possible to reduce warping, deflection, and unevenness near a mounting component in a wireless module, to reduce torsional stress applied to the electrode (in the case of an IC, a solder bump portion) of the mounting component, and to reduce defective mounting.

In the foregoing embodiments, although a case where a Cu core ball is used as the connecting members 18 has been described, the present invention is not limited thereto, and a circular shape or a polygonal shape may be used insofar as the connection member has a columnar shape.

In the foregoing embodiments, the six connecting members 18 are arranged at each of one end (left side) and the other end (right side) in the X direction of the first board 11 shown in FIG. 3. The connecting members 18 are arranged in a line in an order of the connection members for ground, signal transmission, ground, ground, signal transmission, and ground in the Y direction.

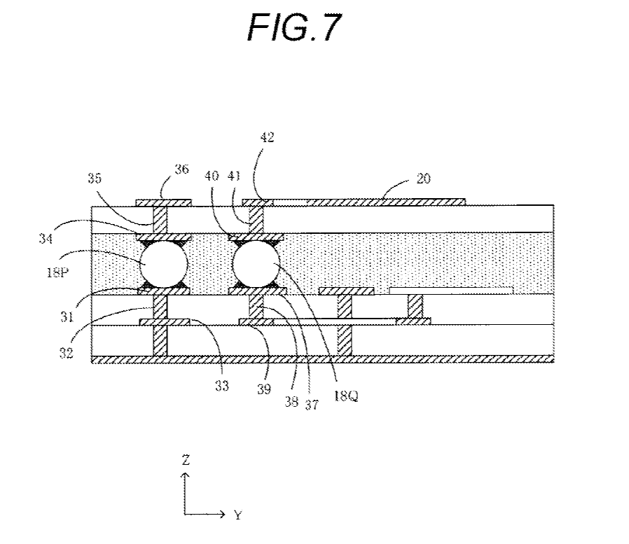

FIG. 7 is a cross-sectional view of the wireless module shown in FIG. 3 taken along the line A-A. In FIG. 7, while the second board 12 is shown, of the six connecting members 18, four connecting members at the other end in the Y direction are not shown.

In FIG. 7, of the two connecting members 18, the connecting member 18P is a ground connecting member. The connecting member 18P is connected to a ground pattern 33 through a wiring pad 31 and a through-via 32 on the first board 11 side. The connecting member 18P is connected to a ground pattern 36 through a wiring pad 34 and a through-via 35 on the second board 12 side.

The connecting member 18Q is a connecting member for signal transmission. The connecting member 18Q is connected to a wiring pattern 39 through a wiring pad 37 and a through-via 38 on the first board 11 side. The connecting member 18Q is connected to a wiring pattern 42 through a wiring pad 40 and a through-via 41 on the second board 12 side. The wiring pattern 42 is connected to an antenna 20. The connecting member 18P is arranged to be closer to one end (left side) in the Y direction than the connecting member 18Q.

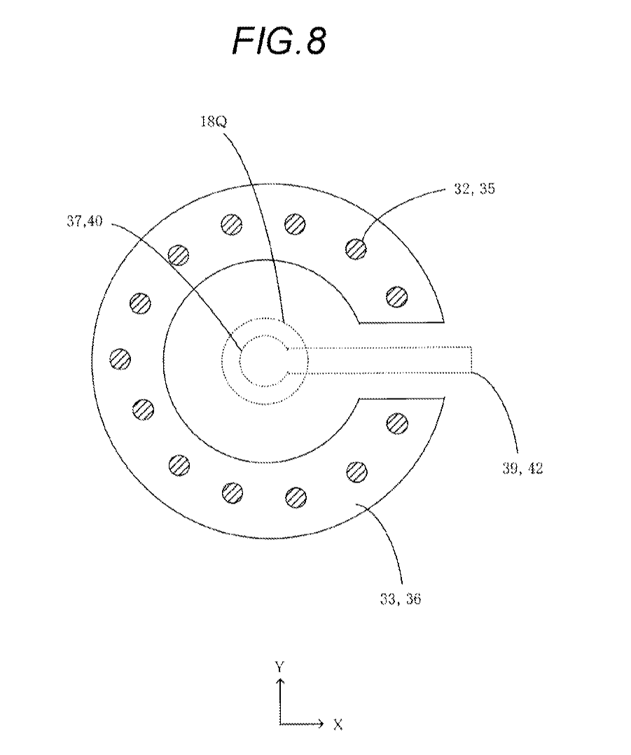

FIG. 8 shows another configuration example of the periphery of the through-vias 32, 35 connected to the ground patterns 33, 36. In this configuration example, the first board 11 is provided with a substantially arc-like ground pattern 33 so as to surround the connecting member 18Q for signal transmission. In the wireless module, the second board 12 is provided with a substantially arc-like ground pattern 36 so as to surround the connecting member 18Q for signal transmission.

That is, a plurality of ground connecting members 18P are arranged so as to surround the connecting member 18Q for signal transmission. Though not shown in FIG. 8, the respective ground connecting members 18P are connected to the through-vias 32, 35 through the wiring pads 31, 34.

In FIG. 8, the ground pattern 33 is substantially formed in a C shape so as to surround the wiring pattern 39. The ground pattern 33 is provided with one or more through-vias 32, and the ground pattern 33 of the first board 11 and the respective ground connecting members 18P are electrically connected together by the through-vias 32.

Similarly, in FIG. 8, the ground pattern 36 is substantially formed in a C shape so as to surround the wiring pattern 42. The ground pattern 36 is provided with one or more through-vias 35, and the ground pattern 36 of the second board 12 and the respective ground connecting members 18P are electrically connected together by the through-vias 35.

The wiring pads 31, 34 are an example of a first wiring pad. The through-vias 32, 35 are an example of a first via. The wiring pads 37 and 40 are an example of a second wiring pad. The through-vias 38, 41 are an example of a second via.

In this way, the wiring pads 37 and 40 for signal transmission, the through-vias 38, 41, and the through-vias 38, 41 are surrounded by the ground wiring pads 31, 34, the through-vias 32, 35, and the ground patterns 33, 36, thereby reducing leakage of an electromagnetic field. The ground pattern and the signal line is at a specific gap, for example, 100 μm to 200 μm, thereby measuring a signal using a high-frequency probe.

### Background to Another Aspect of the Present Disclosure

In the related art, an imaging apparatus is known, in which a semiconductor chip having a high-frequency circuit with a transmitter generating a high-frequency signal and a patch antenna formed on one surface of a semiconductor board is mounted on a MMIC (Monolithic Microwave Integrated Circuits) board (see Reference Patent: Literature: JP-A-2004-205402).

There are many cases where the patch antenna and the high-frequency circuit are different in length (height) in the thickness direction of the board. In this case, when mounting a module board on another board, if the module board is picked up from the mounting surface of the patch antenna, the tip of a pickup tool (suction apparatus) may interfere with an electronic component (for example, the high-frequency circuit including the transmitter).

In the following embodiments, a wireless module in which, even when an electronic component is mounted on an antenna mounting surface of a wireless module, the wireless module can be easily picked up from the antenna mounting surface will be also described.

### Fourth Embodiment

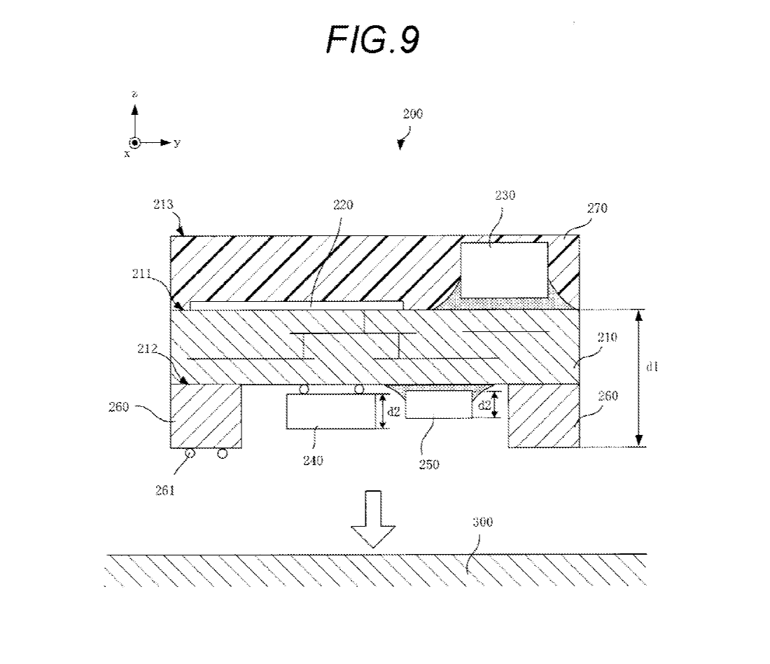

FIG. 9 is a cross-sectional side view showing a configuration example of a wireless module according to a fourth embodiment of the invention.

In a wireless module 200 shown in FIG. 9, a module board 210 is a multi-layered board, and wiring of an IC or the like is performed. Electronic components, such as an antenna unit 220 and a Tcxo 230 (Temperature compensated crystal Oscillator), are mounted on a first surface 211 (in FIG. 9, an upper surface) of the module board 210. Accordingly, the first surface 211 is an antenna mounting surface on which the antenna unit 220 is provided.

The antenna unit 220 is, for example, a patch antenna which is formed by an antenna pattern using wiring. Electronic components, such as a chip component 240 including an RLC and an IC component 250, are mounted on a second surface 212 (in FIG. 9, a lower surface) of the module board 210.

The wireless module 200 is mounted on a set board 300. In this case, the second surface 212 of the module board 210 comes into contact with the mounting surface of the set board 300. A frame board 260 is arranged on the second surface 212 of the module board 210 such that the set board 300 does not come into direct contact with the electronic components mounted on the second surface 212. The frame board 260 has, for example, a square shape and is arranged in a circumferential end portion of the second surface 212 of the module board 210. In this case, the wireless module 200 has a cavity type structure by the module board 210 and the frame board 260. The module board 210 may be constituted by a multi-layered board.

An electrode 261 of the frame board 260 is soldered to the set board 300, and physically and electrically connected to the set board 300. Accordingly, electrical conduction is provided between the frame board 260 as well as the module board 210 and the set board 300 to allow signal transmission.

A length d1 in the board thickness direction (in FIG. 9, z direction) of the module board 210 and the frame board 260 is, for example, about 1 mm. A length d2 in the component thickness direction (in FIG. 9, the z direction) of the chip component 240 or the IC component 250 is, for example, about 0.2 to 0.3 mm. Even if the wireless module 200 including the frame board 260 is mounted on the set board 300, the electronic components mounted on the module board 210 do not come into contact with the set board 300.

On the first surface 211 of the module board 210, the electronic components, such as the antenna unit 220 and the Tcxo 230, are molded integrally by a mold member (for example, mold resin), and a molded portion 270 is formed. The molded portion 270 surrounds the antenna unit 220 and the peripheral electronic component. There is no particular restriction to the mold member, and it should be noted that a mold member having a small dielectric tangent (tanδ) has little electric loss in the molded portion 270.

In this embodiment, when the wireless module 200 is mounted on the set board 300, the wireless module 200 is picked up from the first surface 211 of the module board 210 by a pickup apparatus and mounted on the set board 300. Accordingly, the molded portion 270 is picked up, whereby it is possible to prevent interference during pickup due to the step between the antenna unit 220 and the electronic component provided on the first surface 211, and it becomes easy to pick up the wireless module 200.

It is desirable that a circumferential end surface 213 (ceiling surface) of the molded portion 270 is in parallel to the module board 210 and kept flat. Accordingly, the wireless module 200 can be more easily picked up by absorption.

In this way, the wireless module 200 of this embodiment is a wireless module which is picked up from the first surface 211 as the antenna mounting surface having the antenna unit 220 mounted thereon. The wireless module 200 includes the module board 210 on which the antenna unit 220 is mounted, and the molded portion 270 in which the electronic component including the antenna unit 220 is molded on the first surface 211 of the module board 210. Accordingly, certainty of suction by the pickup tool is improved. That is, even when an electronic component is mounted on an antenna mounting surface of a wireless module, the wireless module can be easily picked up from the antenna mounting surface.

### Fifth Embodiment

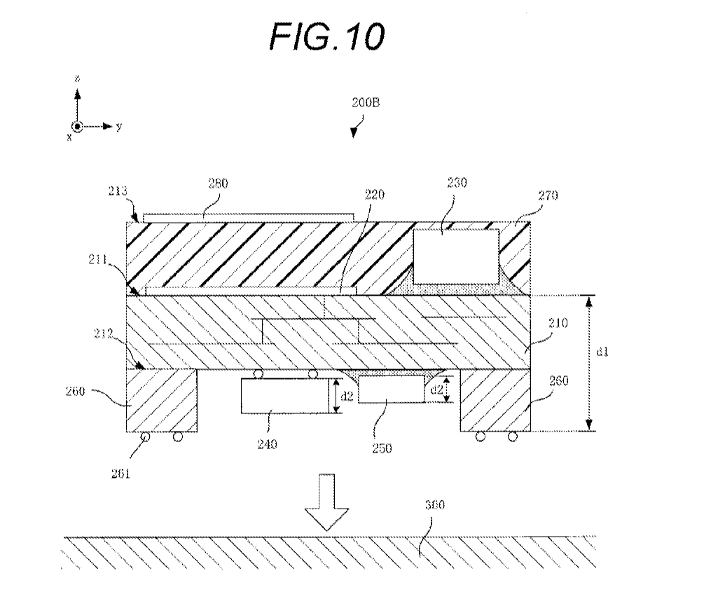

FIG. 10 is a cross-sectional side view showing a configuration example of a wireless module according to a fifth embodiment of the invention.

A wireless module 200B shown in FIG. 10 is different from the wireless module 200 shown in FIG. 9 in that the wireless module 200B includes a waveguide unit 280.

As shown in FIG. 10, the waveguide unit 280 is provided on the circumferential end surface 213 (molded surface) of the molded portion 270 and supports transmission and reception of electric waves by the antenna unit 220. The waveguide unit 280 is formed by for example, a conductor pattern which functions as a wave director.

Usually, since the mold resin forming the molded portion 270 does not take into consideration the antenna characteristics, the mold resin is an undesirable dielectric when viewed from the antenna unit 220. Although the antenna unit 220 is formed assuming air (dielectric constant ε=1), resin having a dielectric constant ε=3 to 4 surrounds the antenna, whereby change in the characteristic of the antenna may occur. The wireless module 200B includes the waveguide unit 280, thereby readjusting the antenna characteristic and maintaining the antenna characteristic in a favorable state.

As a position at which the waveguide unit 280 is provided on the molded portion 270, the following three patterns are considered.

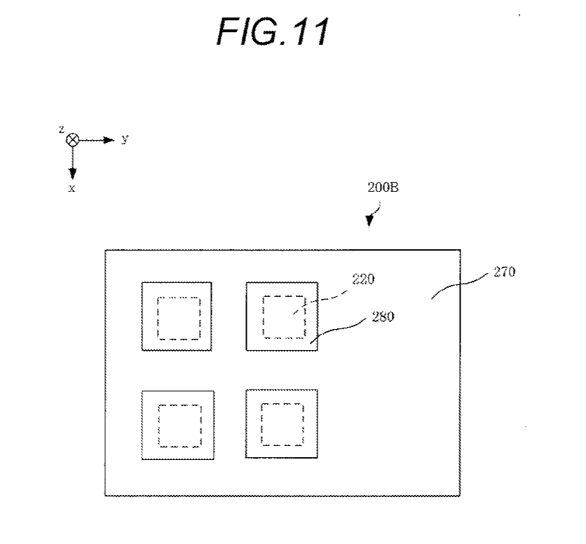

FIG. 11 is a top view showing a first example of the positional relationship between the antenna unit 220 and the waveguide unit 280 of the wireless module 200B.

In the first example, the waveguide unit 280 is provided at a position facing the antenna unit 220 on the circumferential end surface 213 of the molded portion 270. Accordingly, loss of power transmitted or received through the antenna unit 220 is minimized, and transmission and reception of electric waves can be favorably performed. That is, it is possible to improve certainty of suction by the pickup tool and to maintain the antenna characteristic in a favorable state. On the circumferential end surface 213 of the molded portion 270, the waveguide unit 280 is provided outward of the molded portion 270.

In the example shown in FIG. 11, the antenna unit 220 has a 2×2 array configuration on the first surface 211 of the module board 210. Similarly, the waveguide unit 280 has a 2×2 array configuration on the circumferential end surface 213 of the molded portion 270. The antenna unit 220 and the waveguide unit 280 have a 2×2 array configuration, making it easy to perform phase composition or amplitude composition. The 2×2 array configuration of the antenna unit and the waveguide unit 280 is an example, and a single pattern may be provided or more patterns may be arranged in a lattice shape. The arrangement of multiple patterns ensures a favorable antenna characteristic.

The waveguide unit 280 shown in FIG. 11 is provided, and a pattern which functions as the waveguide unit 280 of the molded portion 270 appropriately changes without redesigning the module board 210, thereby changing an antenna gain or the frequency characteristic of the antenna gain. Although pattern cut of the antenna unit 220 for adjusting manufacturing variation after molding is difficult, this becomes possible by cutting the pattern on the molded portion 270.

Since the molded portion 270 is provided to cause an increase in the thickness (in FIG. 10, the length in the z direction) of a dielectric layer having a dielectric constant higher than air, it is preferable that the waveguide unit 280 is greater than the antenna unit 220. That is, it is preferable that a region where the waveguide unit 280 is provided on the molded surface of the molded portion 270 is greater than a region where the antenna unit 220 is provided on the antenna mounting surface. Accordingly, it is possible to further favorably adjust the antenna characteristic.

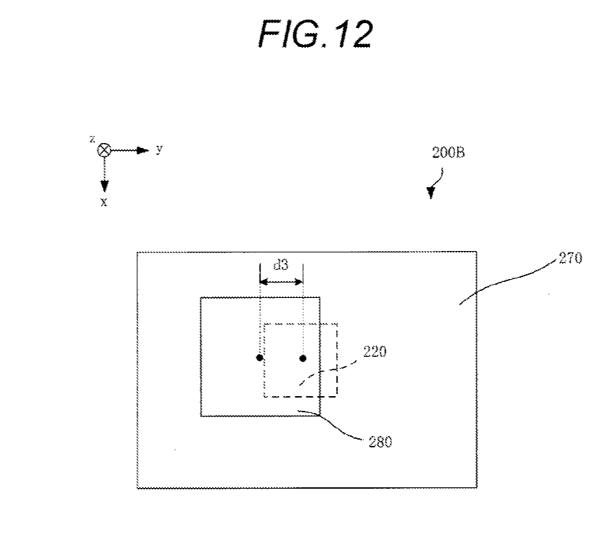

FIG. 12 is a top view showing a second example of the positional relationship between the antenna unit 220 and the waveguide unit 280 of the wireless module 200B.

In the second example, the waveguide unit 280 is provided at a position away from a position facing the antenna unit 220 on the circumferential end surface 213 of the molded portion 270 by a predetermined distance d3. That is, the position on the molded surface of the waveguide unit 280 is deviated (offset) from the position on the antenna mounting surface of the antenna unit 220.

For example, as shown in FIG. 12, when the waveguide unit 280 is on the left side from the antenna unit 220, electric waves are radiated in the left direction. When the waveguide unit 280 is on the right side from the antenna unit 220, electric waves are radiated in the right direction. In this way, the waveguide unit 280 is arranged so as to be deviated in a direction to radiate electric waves.

The waveguide unit 280 is provided to change the pattern on the circumferential end surface 213 of the molded portion 270 without redesigning the module board 210, thereby changing antenna directionality (tilting beams). Even after the antenna unit 220 is mounted on the module board 210, it is possible to flexibly change antenna directionality.

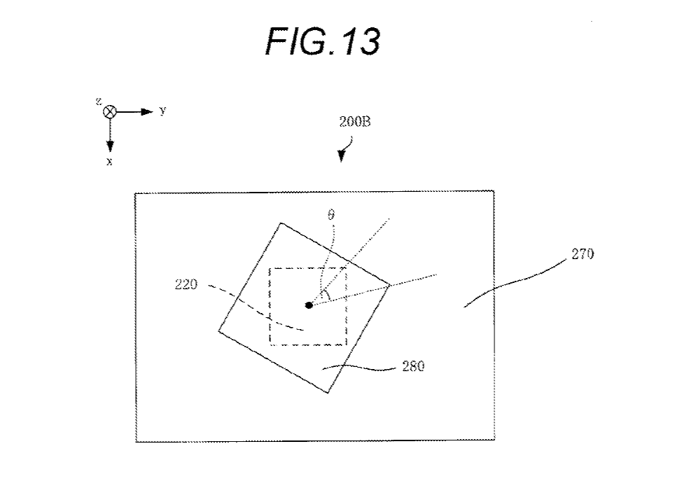

FIG. 13 is a top view showing a third view of the positional relationship between the antenna unit 220 and the waveguide unit 280 of the wireless module 200B.

In the third example, as shown in FIG. 13, on the circumferential end surface 213 of the molded portion 270, the waveguide unit 280 is provided in a region rotated from a region, in which the antenna unit 220 is provided on the antenna mounting surface, by a predetermined rotation angle θ. That is, in FIG. 13, the waveguide unit 280 is mounted on the circumferential end surface 213 in a positional relationship that the direction of a rectangle representing the region of the waveguide unit 280 is rotated from the direction of a rectangle representing the region of the antenna unit 220. Accordingly, it is possible to change the polarization plane (antenna polarization plane) of electric waves radiated from the antenna unit 220.

The position of the waveguide unit 280 on the molded surface and the position (the position on the xy plane) of the antenna unit 220 on the antenna mounting surface are substantially identical. The rotation angle θ is an angle which is less than 90 degrees. The rotation angle θ is adjusted, whereby the antenna polarization plane can be made as a desired polarization plane according to the magnitude of the rotation angle θ. For example, the antenna polarization plane can be changed from a vertical polarization plane to a horizontal polarization plane, can be changed from a horizontal polarization plane to a vertical polarization plane, or can change linearly polarized waves to circularly polarized waves. The change in the antenna polarization plane can be realized by changing the pattern as the waveguide unit 280 on the circumferential end surface 213 of the molded portion 270 without redesigning the module board 210.

Instead of making the positional relationship between the waveguide unit 280 and the antenna unit 220 as a rotation-positional relationship, it may be desired such that the resonance frequency of the waveguide unit 280 and the resonance frequency of the antenna unit 220 are different from each other. With this, it is possible to change the antenna polarization plane.

For example, the resonance frequencies of the antenna unit 220 and the waveguide unit 280 are deviated slightly from each other such that the resonance frequency of the antenna unit 220 becomes 60 GHz and the resonance frequency of the waveguide unit 280 becomes 59.5 GHz, whereby the excitation timing differs slightly. Accordingly, it is possible to change the antenna polarization plane.

### Summary of an Aspect of the Present Disclosure

A wireless module according to a first aspect of the present disclosure includes: a first board on which a mounting component of a wireless circuit is mounted; a second board which is laminated on the first board; and a connecting member which is connected to at least one of the first board and the second board, and forms a gap allowing mounting of the mounting component between the first board and the second board, wherein the connecting member has a plurality of connecting members arranged uniformly between the first board and the second board.

A wireless module according to a second aspect of the present disclosure is the wireless module according to the first aspect, wherein the plurality of connecting members are arranged symmetrically with respect to a center portion in a planar direction of the boards between the first board and the second board.

A wireless module according to a third aspect of the present disclosure is the wireless module according to the first aspect, wherein an antenna having one or a plurality of antenna devices are arranged on the second board, and

the plurality of connecting members are arranged symmetrically with respect to a center portion in a planar direction of the antenna.

A wireless module according to a fourth aspect of the present disclosure is the wireless module according to the first aspect, wherein the plurality of connecting members are arranged symmetrically with respect to a center portion of the mounting component.

A wireless module according to a fifth aspect of the present disclosure is the wireless module according to any one of the first to fourth aspects, wherein at least one of the plurality of connecting members is connected to either the first board or the second board.

A wireless module according to a sixth aspect of the present disclosure is the wireless module according to any one of the first to fourth aspects, wherein at least one of the plurality of connecting members is different in external dimension from other connecting members.

A wireless module according to a seventh aspect of the present disclosure is the wireless module according to any one of the first to sixth aspects, wherein the connecting member includes a ground connecting member, and the wireless module further includes: a first wiring pad which is formed on the first board or the second board which is connected to the ground connecting member; and a first via which connects the first wiring pad to a ground of the first board or the second board.

A wireless module according to an eighth aspect of the present disclosure is the wireless module according to any one of the first to fourth aspects, wherein the connecting member includes a connecting member for signal transmission, and the wireless module further includes: a second wiring pad which is formed on the first board or the second board which is connected to the connecting member for signal transmission; and a second via which connects the second wiring pad to a wiring portion of the first board or the second board, wherein at least a part around the second via is surrounded by a plurality of first vias.

According to the present disclosure, various modifications and applications by those skilled in the art on the basis of the disclosure of the specification and known techniques without departing from the spirit and scope of the present disclosure are also intended by the present disclosure, and included in a scope to be protected. Also, the respective components in the foregoing embodiments may be arbitrarily combined together without departing from the spirit of the invention.

The present application is based on Japanese Patent Application No. 2011-268042 filed on Dec. 7, 2011, and Japanese Patent Application No. 2012-030897 filed on Feb. 15, 2012, the contents of which are incorporated herein by reference.

### INDUSTRIAL APPLICABILITY

The present disclosure is useful for a wireless module or the like in which it is possible to uniformly adjust the thickness of the module in the wireless module after assembling, and for example, a semiconductor device as an electronic component is mounted on a board for wireless communication in a millimeter-wave band.

### REFERENCE SIGNS LIST

11: first board

12: second board

13, 39, 42: wiring pattern

14: semiconductor device

15, 16, 31, 34, 37, 40: wiring pad

17, 33, 36: ground pattern

18, 18A, 18B, 18C, 18D, 18E, 18P, 18Q: connecting member

20: antenna

21, 32, 35, 38, 41: through-via

22: seal resin

200, 200B: wireless module

210: module board

220: antenna unit

230: Tcxo

240: chip component

250: IC component

260: frame board

261: electrode

270: molded portion

280: waveguide unit

300: set board

211: first surface (antenna mounting surface) of module board

212: second surface of module board

213: circumferential end surface (molded surface) of molded portion

1. A wireless module, comprising:
a first board on which a mounting component of a wireless circuit is mounted;
a second board which is laminated on the first board; and
a plurality of connecting members, each of which is connected to at least one of the first board and the second board, and forms a gap allowing mounting of the mounting component between the first board and the second board, wherein
the plurality of connecting members are arranged at a symmetrical position with respect to a center portion of the mounting component, and arranged at an asymmetrical position with respect to a center position between the first board and the second board.

2. The wireless module according to claim 1, wherein
the plurality of connecting members are arranged symmetrically with respect to a center portion in a planar direction of the boards between the first board and the second board.

3. The wireless module according to claim 1, wherein
an antenna having one or a plurality of antenna devices are arranged on the second board, and
the plurality of connecting members are arranged symmetrically with respect to a center portion in a planar direction of the antenna.

4. (canceled)

5. The wireless module according to claim 1, wherein
at least one of the plurality of connecting members is connected to either the first board or the second board.

6. The wireless module according to claim 1, wherein
at least one of the plurality of connecting members is different in external dimension from other connecting members.

7. The wireless module according to claim 1, wherein
the plurality of connecting members include a ground connecting member, and
the wireless module further comprises:
a first wiring pad which is formed on the first board or the second board which is connected to the ground connecting member; and
one or more first vias which connect the first wiring pad to a ground of the first board or the second board.

8. The wireless module according to claim 7, wherein
the plurality of connecting members include a connecting member for signal transmission, and
the wireless module further comprises:
a second wiring pad which is formed on the first board or the second board which is connected to the connecting member for signal transmission; and
a second via which connects the second wiring pad to a wiring portion of the first board or the second board, wherein
at least a part around the second via is surrounded by the more first vias.
